(19) United States
(12) Patent Application Publication
(10) Pub. No.: US 2010/0200879 A1
(43) Pub. Date: Aug. 12, 2010

(54) PHOTOELECTRIC SEMICONDUCTOR DEVICE

(76) Inventors: Tien-Yu Lee, Taipei City (TW); Chia-Hao Wu, Taipei City (TW); Chen-Hsiu Lin, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/548,446

(22) Filed: Aug. 27, 2009

(30) Foreign Application Priority Data
Feb. 9, 2009 (TW) 098104035

(51) Int. Cl. H01L 33/00

(52) U.S. Cl. 257/98; 257/99; 257/E33.067; 257/E33.058

(57) ABSTRACT

A photoelectric semiconductor device has a metal wiring layer packed or embedded into a housing for enhancing package stability and electric connectivity. The housing has a cavity structure, and at least one LED chip and an encapsulating material are configured inside the cavity structure. The metal wiring layer locates inside the housing, or in other words, between the top surface and the bottom surface of the housing, and extends to the bottom of the cavity structure to electrically connect the LED chip. With fully wrapping around, the metal wiring layer has higher stability and more reliability from being harmed by outside changes in humidity and temperature.

### BACKGROUND OF THE INVENTION

1. Field of the Invention

The present invention relates to a photoelectric semiconductor device, and more specifically, to a photoelectric semiconductor device that packs its metal wiring layer inside the housing for improving packaging and electrical stabilities.

2. Description of the Prior Art

Light emitting diode (LED) devices have been outstanding in energy-saving lighting with its features of small size, long device lifetime, high durability, environmental friendliness, and low power consumption. Of all the LEDs, white light LED (or LED with compound lights) combines two or more monochromatic lights and has been widely used in indicating lamps and display devices in information technology, communications, and consumer electronics products. In addition to improving the light emission efficiency, the unevenness of lights from the LED also requires an urgent solution in the study of compound LED.

Please refer to FIG. 1, which is an illustration of an LED device 9 disclosed in the U.S. Pat. No. 6,670,751. The LED device 9 includes a ceramic substrate 1, a first ceramic plate 2 mounted on the ceramic substrate 1, an insulating layer 6, a second ceramic plate 7, an LED chip 3, electrodes 4, and a heat dissipating hole 8 for dissipating heat generated by the LED chip 3. The metal-wire 5 is bonded to the electrodes 4 for further electrically connecting between the LED chip 3 and the electrodes 4.

Such packaging method that packs the metal-wire 5 with high polymer colloid as shown as the insulating layer 6 in FIG. 1 or other types of packaging methods in the prior art, however, configures the metal wiring layer formed by the metal-wire 5 and the electrodes 4 on the surfaces of the ceramic substrate 1 and the first ceramic plate 2, with the high polymer colloid covering thereon. Since the high polymer colloid and the ceramic substrate are of different material properties, packaging of the LED device with such prior art method acquires no robustness for the package, i.e., the high polymer colloid may easily break off from the substrate and the metal wiring layer exposes. On the other hand, by simply covered by the high polymer colloid on the surface of the substrate, the metal wiring layer is vulnerable in its conductivity by corrosion of humidity from lateral invasion or above penetrating through the high polymer colloid, or the effect of temperature. Electrical conductivity is damaged.

### SUMMARY OF THE INVENTION

The present invention provides a photoelectric semiconductor device. The photoelectric semiconductor device includes a light emitting diode (LED) chip, an encapsulating material covering on the LED chip and containing at least one fluorescent powder, a housing having a cavity structure, and a metal wiring layer. The LED chip and the encapsulating material are configured in the cavity structure, and the metal wiring layer is configured inside the housing, extending to the bottom of the cavity structure and electrically connected to the LED chip.

The present invention also provides a light emitting device. The light emitting device includes a base, a cavity body having a cavity structure, a metal wiring layer formed between the base and the cavity body, extending to the cavity structure, a light emitting chip configured in the cavity structure and on the metal wiring layer, and a fluorescent powder layer formed on the light emitting chip.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration of an LED device according to the prior art.

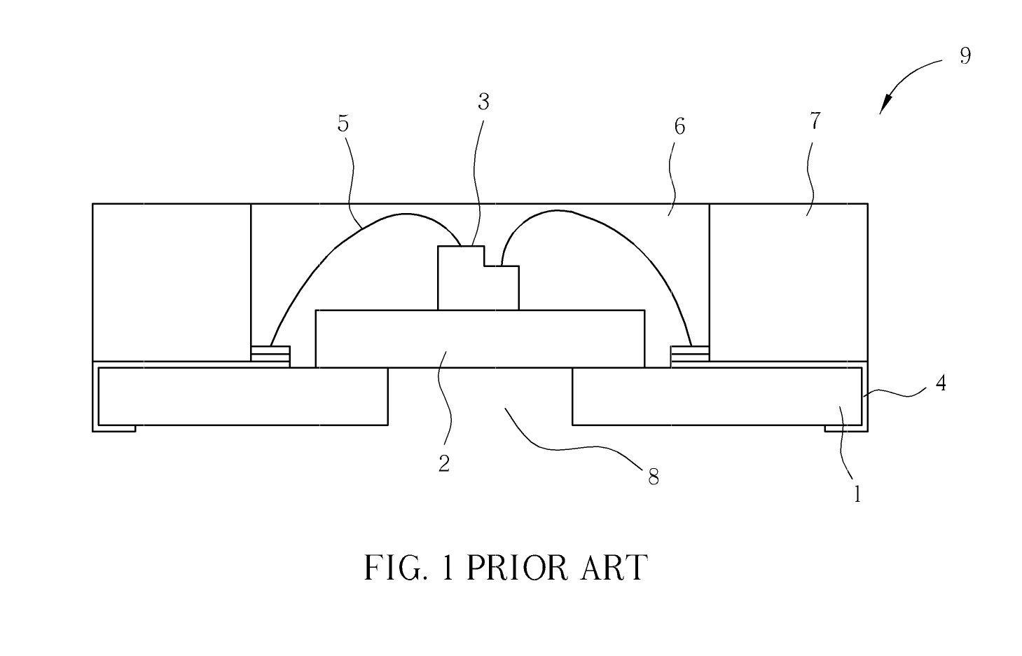

FIG. 2 is an illustration of one embodiment according to the present invention.

FIG. 3 is an illustration of another embodiment according to the present invention.

FIG. 4 is an illustration of partial perspective view of the embodiment in FIG. 3.

### DETAILED DESCRIPTION

Photoelectric semiconductor devices such as LED devices disclosed in the present invention, taking their dimension and luminance strength into consideration, a cavity structure is introduced into the housing as to package an LED chip. An encapsulating material with fluorescent powder is covering on the cavity structure after the LED chip is placed therein. Emitting white lights with high evenness in all directions is accomplished by applying such packaging design.

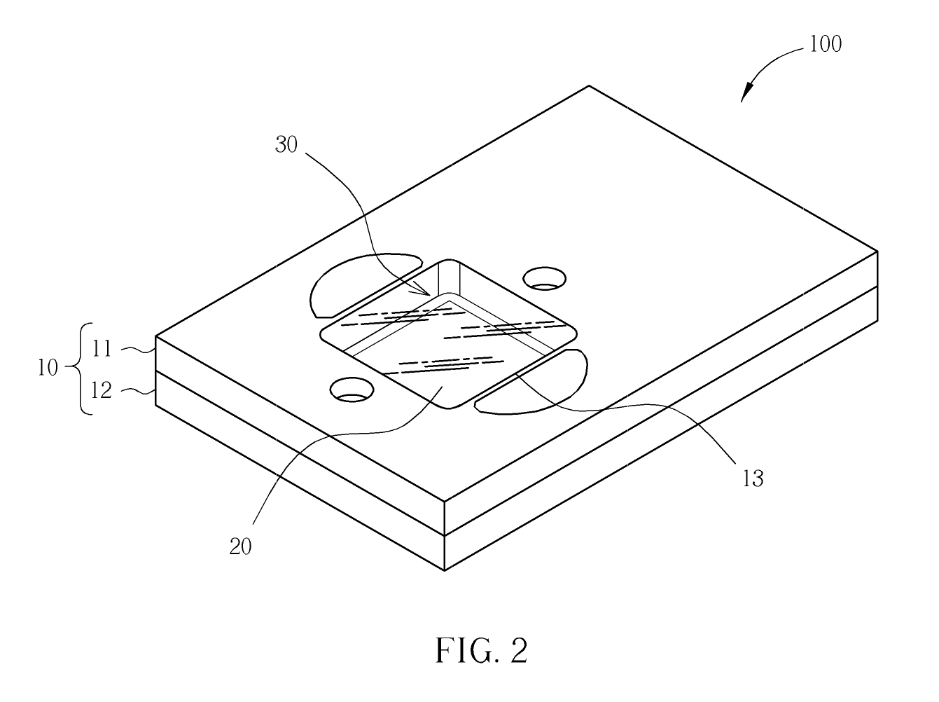

Please refer to FIG. 2. FIG. 2 is an illustration of one embodiment according to the present invention. A photoelectric semiconductor device 100 is provided. The photoelectric semiconductor device 100 includes a housing 10 made of electrically insulated material, at least a light emitting diode (LED) chip 20, and an encapsulating material 30. The housing 10 includes a cavity body 11 and a base 12. The cavity body 11 has a cavity structure 13 for containing the LED chip 20, with corresponding shape in view of the shape of the LED chip 20 preferably. While in this embodiment, each side surface of the cavity structure 13 is facing and substantially parallel with corresponding side wall of the LED chip 20. For example, most LED chips 20 are cubic or regular polygonal and the cavity structure 13 is correspondingly cubic or regular polygonal. The side surfaces of the cavity structure 13, however, can also be tilt relative to the corresponding side walls of the LED chip 20 in other embodiment. Additionally, the LED chip 20 can be direct-type (such as horizontal type or vertical type) chip, flip-chip, or other forms, that can give out lights with wavelength ranging from ultraviolet (UV) to infrared ray (IR). In this embodiment, taking GaN chip as an example, a preferred wavelength range could be blue lights or green lights under 500 nanometer (nm). Furthermore, the electrically insulated material that forms the housing 10 can also be material with high thermal conductivity, such as Al₂O₃, AlN, Si or other ceramic materials having high thermal conductivity and can be made in a mold process. The encapsulating material 30 includes at least one kind of fluorescent powder that, for example, can transform the blue lights or the UV lights emitted from the LED chip 20 into yellow lights having wavelength ranging from 520 nm to 570 nm. This embodiment of the invention can also mix the first lights emitted from the LED chip 20 and the second lights transformed by the fluorescent powder to produce polychromatic light, such as the white light in particular. In the photoelectric semiconductor device 100, the encapsulating material 30 is fully covering around the LED chip 20 and filled in the cavity structure 13 of the housing 10.

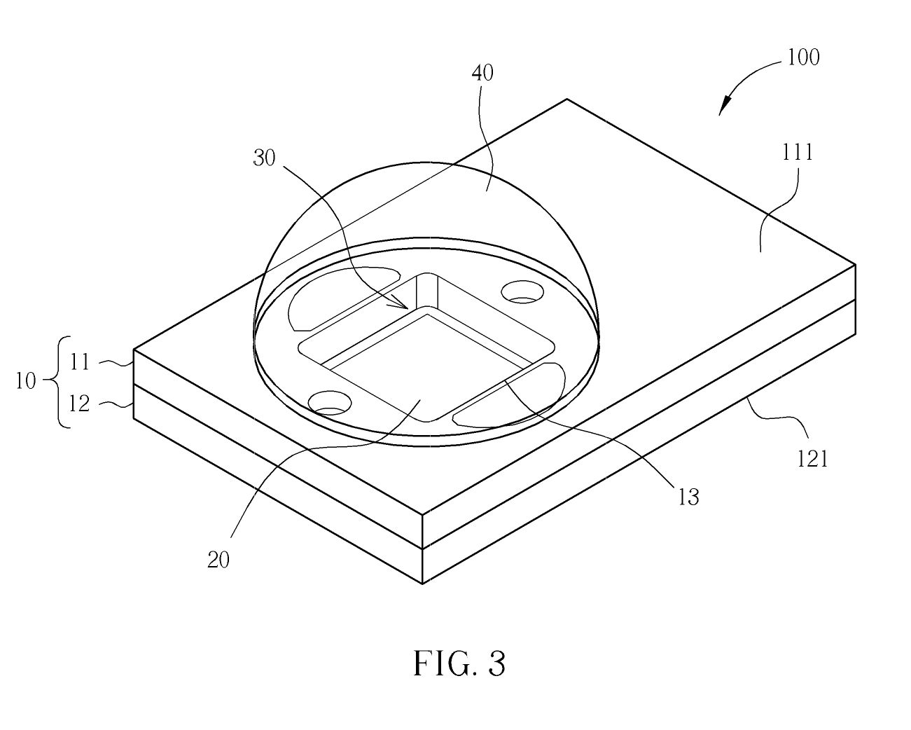

Please refer to FIG. 3. FIG. 3 is an illustration showing another embodiment of the present invention. The photoelectric semiconductor device 100 further includes an optical lens 40 configured above the cavity structure 13 of the housing 10. The optical lens 40 can be formed above the LED chip 20 and the encapsulating material 30 by molding so as to tightly stick to the encapsulating material 30. Light transmitting path can be shortened accordingly and the photoelectric semiconductor device 100 can have best efficiency and ruminant angle. On the other hand, the optical lens 40 being tightly sticking to the encapsulating material 30 can also effectively reduce overall packaging thickness. With no other packaging materials, except the encapsulating material 30 introduced between the optical lens 40 and the light source (the LED chip 20), projection effect caused by interaction of the packaging material and the light that leads to non-uniform chromatic can also be effectively eliminated. In this embodiment, the optical lens 40 can also be made of light-transmitting material with high light transmittance such as epoxy or silicon as the encapsulating material 30. Other types of high light-transmitting materials can also be applied as forming the optical lens 40, and the material of the optical lens 40 is different from the encapsulating material 30 thereof.

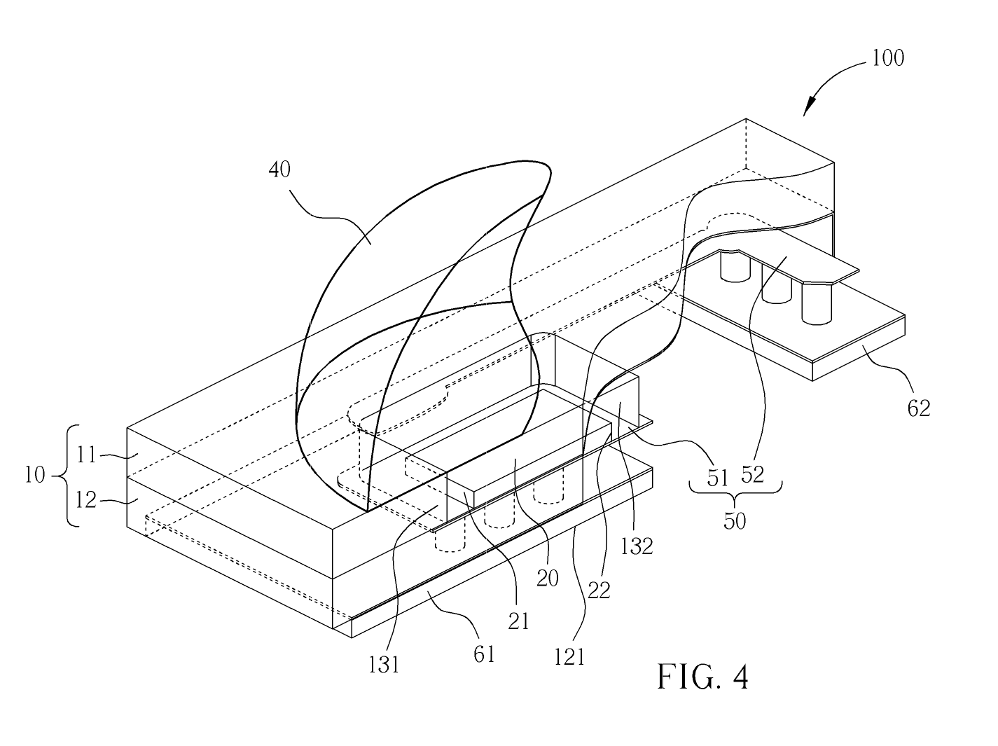

Please refer to FIG. 4, which is a partial perspective view of the embodiment in FIG. 3. The photoelectric semiconductor device 100 further includes a metal wiring layer 50 that electrically connects to the wiring of a printed circuit board where the photoelectric semiconductor device 100 is installed and provides current for the LED chip 20. The metal wiring layer 50 includes a first metal pad 51 and a second metal pad 52 separate with each other and forms a circuit with the LED chip 20. The first metal pad 51 and the second metal pad 52 are configured inside the housing 10, and more specifically, between the cavity body 11 and the base 12, and extend to the bottom of the cavity structure 13 wherein the first metal pad 51 is further exposed at the bottom of the cavity structure 13 to electrically connect to the LED chip 20. Additionally, the first metal pad 51 can be electrically connected to the second metal pad 52 via wire bonding, or other manner known to those skilled in the art. To put it further, the structure of the housing 10 provides a die mounting area for the LED chip 20, wherein the die mounting area and the base 12 are substantial coplanar so as to provide high packaging stability for the metal wiring layer 50. In this embodiment, both the first metal pad 51 and the second metal pad 52 extend downward from inside the housing 20 outward the housing 20 for dissipating heat. A heat dissipating structure includes a first heat dissipating plate 61 and a second heat dissipating plate 62, each extending right under the first metal pad 51 and the second metal pad 52 respectively and disposed at the bottom surface 121 of the base 12. The first heat dissipating plate 61 and the second heat dissipating plate 62 connect to the first metal pad 51 and the second metal pad 52 respectively and can further bring out heat generated by the LED chip 20. The second heat dissipating plate 62 is also made of conductive material and has electrical connection.

On the other hand, considering the dimension and lamination strength of the LED chip 20, in the embodiment of the present invention, each side surface of the cavity structure 13 is substantially parallel with the corresponding surface of the LED chip 20, with practically distance less than 0.6 millimeter (mm). In FIG. 4, for example, a first surface 21 of the LED chip 20 is substantially parallel and distanced from a first side surface 131 of the cavity structure 13 with less than 0.6 mm. A second surface 22 of the LED chip 20 is substantially parallel and distanced from a second side surface 132 of the cavity structure 13 with less than 0.6 mm.

In the aforementioned embodiments, the housing 10 of the photoelectric semiconductor device 100 is a two-tier structure that includes the cavity body 11 and the base 12, and the metal wiring layer 50 is packed between the two structures. In other embodiments, however, an integrally made housing can also be application, with a cavity structure having proper depth for containing the LED chip. The metal wiring layer is then embedded inside the integral housing and extends to the cavity structure to electrically connect to the LED chip, which is to say, the metal wiring layer can be configured at an arbitrary height inside the housing between the top surface (similar to the top surface 111 in FIG. 3) and the bottom surface (similar to the bottom surface 121 in FIG. 3) of the housing. Since securely packaged by the housing, the metal wiring layer is invulnerable to humidity or temperature change from the outside, or free from breaking off with the encapsulating material. Stability and conductivity of the metal wiring layer is guaranteed.

The LED device (or photoelectric semiconductor device) in the present invention implements a metal wiring layer packed or embedded into a housing so that the package stability and electric connectivity of the LED device is enhanced. The housing has the cavity structure, and the LED chip and the encapsulating material are configured inside the cavity structure. The metal wiring layer locates inside the housing or in other words, between the top surface and the bottom surface of the housing, and extends to the bottom of the cavity structure to electrically connect the LED chip. With fully wrapping around, the metal wiring layer has higher stability and more reliability from being harmed by outside changes in humidity and temperature.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A photoelectric semiconductor device, comprising:
a light emitting diode (LED) chip;
an encapsulating material covering on the LED chip and containing at least one fluorescent powder;
a housing having a cavity structure, wherein the LED chip and the encapsulating material are configured in the cavity structure; and
a metal wiring layer configured inside the housing, extending to the bottom of the cavity structure and electrically connected to the LED chip.

2. The photoelectric semiconductor device of claim 1, wherein the housing is made of Al₂O₃, AlN, Si, or other ceramic materials having high thermal conductivity.

3. The photoelectric semiconductor device of claim 1, wherein the surfaces of the cavity structure are substantially parallel with corresponding surfaces of the LED chip.

4. The photoelectric semiconductor device of claim 1, wherein the distance between each surface of the cavity structure and each corresponding surface of the LED chip is less than 0.6 mm.

5. The photoelectric semiconductor device of claim 1, further comprising an optical lens configured above the cavity structure of the housing and covering the LED chip and the encapsulating material.

6. The photoelectric semiconductor device of claim 5, wherein the optical lens and the encapsulating material are made of light-transmitting materials such as epoxy or silicon.

7. The photoelectric semiconductor device of claim 1, wherein the housing comprises a top surface and a bottom surface, and the metal wiring layer is configured between the top surface and the bottom surface of the housing.

8. The photoelectric semiconductor device of claim 1, further comprising a heat dissipating structure, the metal wiring layer connecting to the heat dissipating structure within the housing.

9. The photoelectric semiconductor device of claim 8, wherein the housing comprises a top surface and a bottom surface, and the metal wiring layer is configured between the top surface and the bottom surface of the housing.

10. The photoelectric semiconductor device of claim 9, wherein the heat dissipating structure is configured to the bottom surface of the housing.

11. The photoelectric semiconductor device of claim 1, wherein the metal wiring layer comprises two separate metal pads.

12. The photoelectric semiconductor device of claim 11, wherein the two separate metal pads extends downward from inside the housing outward the housing for dissipating heat.

13. The photoelectric semiconductor device of claim 12, further comprising two heat dissipating plates connecting to the two metal pads respectively.

14. The photoelectric semiconductor device of claim 1, wherein the housing comprises a cavity body and a base, the cavity structure is configured in the cavity body, and the metal wiring layer is configured between the cavity body and the base and extends to the bottom of the cavity structure.

15. The photoelectric semiconductor device of claim 14, wherein the metal wiring layer comprises two separate metal pads and one of the metal pads is further exposed at the bottom of the cavity structure to electrically connect to the LED chip.

16. The photoelectric semiconductor device of claim 1, wherein the housing is made in a mold process.

17. A light emitting device, comprising:
a base;
a cavity body having a cavity structure;
a metal wiring layer formed between the base and the cavity body, wherein the metal wiring layer extends to the cavity structure;
a light emitting chip configured in the cavity structure and on the metal wiring layer; and
a fluorescent powder layer formed on the light emitting chip.

18. The light emitting device of claim 17, wherein the fluorescent powder layer fills in the cavity structure of the cavity body.

19. The light emitting device of claim 17, wherein the metal wiring layer comprises two separate metal pads.

20. The light emitting device of claim 19, further comprising a heat dissipating structure connecting to the metal wiring layer for dissipating heat generated by the light emitting chip.

21. The light emitting device of claim 20, wherein the two separate metal pads connect to the heat dissipating structure respectively.
